(19) United States
(12) Patent Application Publication
(10) Pub. No.: US 2023/0132008 A1
(43) Pub. Date: Apr. 27, 2023

(54) Optical Sensor, Optical Distance Sensing Modlule and Fabricating Method Thereof

(71) Applicant: Egis Technology Inc., Hsinchu City (TW)

(72) Inventors: Chen-Chih Fan, Hsinchu City (TW); Bruce C. S. Chou, Hsinchu City (TW)

(21) Appl. No.: 17/886,448

(22) Filed: Aug. 11, 2022

Related U.S. Application Data
(60) Provisional application No. 63/281,735, filed on Nov. 22, 2021.
(60) Provisional application No. 63/272,139, filed on Oct. 26, 2021.

(30) Foreign Application Priority Data
May 31, 2022 (CN) 202210615629.1

(51) Int. Cl. G01S 17/32; H01L 31/16; H01L 31/0216

(52) U.S. Cl. CPC G01S 17/32; H01L 31/16; H01L 31/02164

(57) ABSTRACT

The present disclosure provides an optical sensor, an optical distance sensing module and a fabricating method thereof. According to the embodiments of the present disclosure, the optical sensor includes an optical sensing layer, a light transmitting layer and a light blocking layer. The optical sensing layer includes an array of optical sensing elements, the light transmitting layer is coated on the optical sensing layer, and the light blocking layer includes one or more light incident holes and is coated on the light transmitting layer. The optical sensing layer, the light transmitting layer and the light blocking layer are packaged as a wafer die. Light passes through the light incident holes and transmits through the light transmitting layer to irradiate on the array of optical sensing elements. The optical sensor effectively reduces the thickness, size and weight of the optical sensor, thereby expanding the application range of the optical sensor.

### CROSS-REFERENCE TO RELATED APPLICATIONS

The present application claims priority to Chinese Application No. 202210615629.1, filed May 31, 2022, and to U.S. Provisional Application No. 63/281,735, filed on Nov. 22, 2021, and to U.S. Provisional Application No. 63/272,139, filed on Oct. 26, 2021. All of the aforementioned applications are incorporated herein by reference in their entireties.

### TECHNICAL FIELD

The present disclosure relates to the field of sensor and circuit packaging, and more particularly, to an optical sensor, optical distance sensing module and a fabricating method thereof.

### BACKGROUND

At present, as the most widely used and frequently used devices in daily life, mobile phones and computers are developing rapidly. As one of the most important optical sensing components of mobile phones and computers, a camera plays a very important role in image detection, image capture, image processing, distance detection, motion perception etc. For example, ToF (Time of Flight) lens is a popular distance sensing device, which transmits and receives light beams, calculates the time difference, or phase difference, between the transmitted light and the reflected light, and forms a set of distance depth data, thereby assisting the camera in focusing or obtaining a stereoscopic 3D image model.

At present, a sensor employed in smart devices such as mobile phones and computers is fabricated in such a method that parts of the sensor are pasted or are assembled together in other structural connection manners after they are produced, and finally, all the assembled parts are sealed and packaged to protect the parts in the sensor from being damaged.

Under the above sensor fabricating method, parts are required to cooperate accurately, which is difficult to realize, has increased requirements for fabricating devices and increased costs. At the same time, under such sensor fabricating methods, due to the precision limitation of the fabricating devices, it is difficult to further compress the volume and reduce the size of the sensor so that the sensor can meet the application requirements in more scenarios and meet the increasing development requirements of miniaturization, and light weight of electronic devices.

### SUMMARY

The following summary presents a simplified summary of certain features. The summary is not an extensive overview and it not intended to identify key or critical elements

In order to reduce the thickness and the size of an optical sensor, so that the optical sensor can be applied to more application scenarios, the present disclosure, when fabricating an optical sensor, provides an optical sensing layer that includes an array of optical sensing elements, forms a light transmitting layer on the optical sensing layer by wafer level processing, forms a light blocking layer on the light transmitting layer by wafer level processing, and forms one or more light incident holes on the light blocking layer so that light can pass through the light-incident holes and irradiate onto the array of optical sensing elements through the light transmitting layer.

Since the optical sensor is fabricated based on the wafer level, the optical sensor provided by the present disclosure can effectively reduce the thickness, size and weight of the optical sensor, thereby expanding the application range of the optical sensor.

Aspects of the present disclosure provide an optical sensor comprising: an optical sensing layer, a light transmitting layer and a light blocking layer, wherein the optical sensing layer includes an array of optical sensing elements; the light transmitting layer is coated on the optical sensing layer; and the light blocking layer includes one or more light incident holes and is coated on the light transmitting layer; wherein the optical sensing layer, the light transmitting layer and the light blocking layer are packaged as a wafer die; wherein the light passes through the one or more light incident holes and transmits through the light transmitting layer to irradiate on the array of optical sensing elements.

According to aspects of the present disclosure, the optical sensor further comprising: a light filtering layer for filtering light in a specific wavelength range, wherein the light filtering layer is coated on the optical sensing layer, and the light transmitting layer is coated on the light filtering layer; or the light transmitting layer is coated on the optical sensing layer, and the light filtering layer is coated on the light transmitting layer, wherein the optical sensing layer, the light filtering layer, the light transmitting layer and the light blocking layer are packaged as the wafer die.

According to aspects of the present disclosure, in a case where the light transmitting layer is coated on the light filtering layer, the light blocking layer is coated on an upper surface of the light transmitting layer, or the light blocking layer is coated on the upper surface of the light transmitting layer and at least one side face of the light filtering layer and/or the light transmitting layer, and the one or more light incident holes of the light blocking layer are located on the upper surface of the light transmitting layer; or in a case where the light filtering layer is coated on the light transmitting layer, the light blocking layer is coated on an upper surface of the light filtering layer, or the light blocking layer is coated on the upper surface of the light filtering layer and at least one side face of the light filtering layer and/or the light transmitting layer, and the one or more light incident holes of the light blocking layer are located on the upper surface of the light filtering layer.

Aspects of the present disclosure provide an optical sensor comprising: a substrate layer, a light receiving part located on the substrate layer, and a molding layer, wherein the light receiving part includes an optical sensing layer, a light transmitting layer and a light blocking layer, wherein the optical sensing layer includes an array of optical sensing elements; the light transmitting layer is coated on the optical sensing layer; and the light blocking layer includes one or more light incident holes and is coated on the light transmitting layer; the molding layer packages the light receiving part onto the substrate layer and shapes the optical sensor, and the light receiving part is completely or partially covered by the molding layer; wherein light irradiates on the array of optical sensing elements through the one or more light incident holes.

According to aspects of the present disclosure, the molding layer is made of transparent material, and the molding layer covers at least part of the one or more light incident holes, or the molding layer does not cover the one or more light incident holes at all.

According to aspects of the present disclosure, the refractive index of the transparent material is higher than that of air, so that a light receiving range of the light receiving part is increased.

Aspects of the present disclosure provide an optical sensor fabricating method, comprising: providing an optical sensing layer that includes an array of optical sensing elements; forming a light transmitting layer on the optical sensing layer by wafer level processing; and forming a light blocking layer on the light transmitting layer by wafer level processing, and forming one or more light incident holes on the light blocking layer.

According to aspects of the present disclosure, forming the light transmitting layer on the optical sensing layer further comprises: coating a light filtering layer on the optical sensing layer and coating the light transmitting layer on the light filtering layer by wafer level processing, wherein forming the light blocking layer on the light transmitting layer comprises: coating the light blocking layer on an upper surface of the light transmitting layer, or coating the light blocking layer on the upper surface of the light transmitting layer and at least one side face of the light filtering layer and/or the light transmitting layer by wafer level processing, and locating the one or more light incident holes of the light blocking layer on the upper surface of the light transmitting layer.

According to aspects of the present disclosure, forming the light blocking layer on the light transmitting layer further comprises: coating a light filtering layer on the light transmitting layer and coating the light blocking layer on the light filtering layer by wafer level processing, wherein coating the light blocking layer on the light filtering layer comprises: coating the light blocking layer on the upper surface of the filtering layer or coating the light blocking layer on an upper surface of the light filtering layer and at least one side face of the light filtering layer and/or the light transmitting layer by wafer level processing, and locating the one or more light incident holes of the light blocking layer on the upper surface of the light filtering layer.

Aspects of the present disclosure provide an optical sensor fabricating method, comprising: providing an optical sensing layer that includes an array of optical sensing elements; coating a light transmitting layer on the optical sensing layer; and coating a light blocking layer on the light transmitting layer, and forming one or more light incident holes on the light blocking layer; arranging a light receiving part of the optical sensor on a substrate layer, wherein the light receiving part includes the optical sensing layer, the light transmitting layer and the light blocking layer, packaging the light receiving part of the optical sensor onto the substrate layer by molding.

Aspects of the present disclosure provide an optical distance sensing module, comprising: a substrate layer, and a light emitting part and a light receiving part that are located on the substrate layer, wherein the light emitting part includes a light emitter, and the light receiving part includes an optical sensing layer, a light transmitting layer and a light blocking layer, wherein the optical sensing layer includes an array of optical sensing elements; the light transmitting layer is coated on the optical sensing layer; the light blocking layer comprises one or more light incident holes and is coated on the surface of the light transmitting layer; wherein, the optical sensing layer, the light transmitting layer and the light blocking layer are packaged as a wafer die; the light emitting part and the light receiving part are arranged side by side on the substrate layer, the light emitter emits light, the light is reflected by an external object and then the reflected light enters the one or more light incident holes, wherein the optical distance sensing module detects a distance between the external object and the optical distance sensing module through a time difference and/or phase difference between the light emitted by the light emitter and the reflected light received by the optical sensing element.

Aspects of the present disclosure provide an optical distance sensing module, comprising: a substrate layer, a light emitting part and a light receiving part that are located on the substrate layer, and a molding layer, wherein the light emitting part includes a light emitter, and the light receiving part includes an optical sensing layer, a light transmitting layer and a light blocking layer, wherein the optical sensing layer includes an array of optical sensing elements; the light transmitting layer is coated on the optical sensing layer; the light blocking layer comprises one or more light incident holes and is coated on the surface of the light transmitting layer; the light emitting part and the light receiving part are arranged side by side on the substrate layer, and are completely or partially covered by the molding layer, wherein the light emitter emits light transmitting through the molding layer, and the light is reflected by an external object and then the reflected light enters the one or more light incident holes, wherein the optical distance sensing module detects a distance between the external object and the optical distance sensing module through a time difference and/or phase difference between the light emitted by the light emitter and the reflected light received by the array of optical sensing elements.

According to aspects of the present disclosure, the optical distance sensing module is arranged under a display screen of an electronic device, wherein, the electronic device includes a middle frame, and the optical distance sensing module is connected to the middle frame.

One or more aspects of the present disclosure provide an optical sensor, optical distance sensing module and a fabricating method thereof. According to the present disclosure, the optical sensor includes an optical sensing layer, a light transmitting layer and a light blocking layer, wherein the optical sensing layer includes an array of optical sensing elements; the light transmitting layer is coated on the optical sensing layer; the light blocking layer includes one or more light incident holes and is coated on the light transmitting layer; wherein the optical sensing layer, the light transmitting layer and the light blocking layer are packaged as a wafer die; light passes through the light incident holes and transmits through the light transmitting layer to irradiate on the array of optical sensing elements. The optical sensor provided by the present disclosure can effectively reduce the thickness, size and weight of the optical sensor, thereby expanding the application range of the optical sensor.

These and other features and advantages are described in greater detail below.

### BRIEF DESCRIPTION OF THE DRAWINGS

In order to explain the technical scheme of aspects of the present disclosure more clearly, the drawings needed in the description of one or more aspects herein will be briefly introduced below. Obviously, the drawings in the following description are only some exemplary aspects of the present disclosure. For those of ordinary skill in the art, other drawings may be obtained according to these drawings without any creative effort.

Here, in the drawings:

FIG. 1 is a schematic diagram showing the working scenario of an optical distance sensing module according to the embodiments of the present disclosure;

FIG. 2 is a schematic diagram showing the structure of an optical distance sensing module;

FIGS. 3A to 3E are schematic diagrams showing the structure of an optical sensor according to one or more aspects of the present disclosure;

FIGS. 4A and 4B are schematic diagrams showing the structure of an optical distance sensing module according to one or more aspects of the present disclosure;

FIGS. 5A and 5B are schematic diagrams showing the effect of the molding layer on the field of view (FOV) according to one or more aspects of the present disclosure;

FIGS. 6A to 6C are schematic diagrams showing the installation manner of an optical distance sensing module according to one or more aspects of the present disclosure;

FIG. 7 is a schematic flowchart showing the fabricating method of an optical sensor according to one or more aspects of the present disclosure;

FIGS. 8A to 8C are schematic diagrams showing the fabricating method of an optical sensor according to one or more aspects of the present disclosure;

FIG. 9 is a schematic flowchart showing the fabricating method of an optical distance sensing module according to one or more aspects of the present disclosure; and

FIGS. 10A to 10D are schematic diagrams showing the fabricating method of an optical distance sensing module according to one or more aspects of the present disclosure.

### DETAILED DESCRIPTION

In order to make the objectives, technical scheme and advantages of the present application more apparent, one or more exemplary aspects according to the present application will be described in detail below with reference to the drawings. Obviously, the described aspects are only part of the aspects of the present application, rather than all the aspects of the present application, and it should be understood that the present application is not limited by the examples described herein.

Furthermore, in this specification and the drawings, steps and elements that are substantially the same or similar are denoted by the same or similar reference signs, and repeated descriptions of these steps and elements may be omitted.

Furthermore, in the specification and the drawings, elements are described in singular or plural forms. However, the singular and plural forms are appropriately selected for the proposed situations only for convenience of explanation, which are not intended to limit the present disclosure thereto. Therefore, singular forms may include plural forms, and plural forms may also include singular forms, unless the context clearly indicates otherwise.

Furthermore, in the specification and the drawings, the involved terms “first/second” are only used to distinguish similar objects, and do not represent a specific order of objects. Understandably, “first/second” may be interchanged in a specific order or sequence when allowed, so that the aspects of the present disclosure may be implemented in an order other than those illustrated or described herein.

Furthermore, in the specification and the drawings, the adopted terms such as “upper”, “lower”, “vertical” and “horizontal” which relate to orientation or positional relationship are used only for convenience in describing illustrative aspects according to the present disclosure, and are not intended to limit the present disclosure thereto. Therefore, they should not be construed as a limitation to the present disclosure.

Furthermore, in the specification and the drawings, unless otherwise specified, “connection” does not necessarily mean direct connection or direct contact. Here, “connection” may mean both the function of fixation and connectivity in the sense of electricity.

The optical sensor works mainly with light as the medium, and the optical sensor has a long detection distance, a fast detection speed and high sensitivity, and can realize high-precision detection without contact. The optical sensor may detect the internal condition of an object-to-be-measured without contacting it, which may avoid damage to the object-to-be-measured and the sensor. In this way, not only the safety of the object-to-be-measured may be ensured, but also the optical sensor may be enabled to be used for a long time. The optical sensor may also be used in telemetry, remote control, image information extraction and other fields.

A distance sensor usually transmits and receives light beams, calculates the time difference and/or phase difference between the transmitted light and the reflected light, and forms a set of distance depth data, thereby assisting the camera in focusing or obtaining a stereoscopic 3D image model. At present, the distance sensing technique has been applied in many technical fields, such as obstacle avoidance of unmanned aerial vehicles, driverless cars or robots, automatic handling of mechanical arms, medical monitoring, distance sensing modules of smart phones or computers, AR/somatosensory games, holographic image interaction and so on.

As an example, the present disclosure relates to an optical sensor, an optical distance sensing module and their fabricating methods, and the embodiments of the present disclosure will be further described below with reference to the drawings.

FIG. 1 is a schematic diagram showing the working scenario of an optical distance sensing module according to one or more aspects of the present disclosure.

The optical distance sensing module may use the “flying time” method to determine the distance, that is, the light emitting part in the optical distance sensing module may send outgoing light for distance measurement to an object-to-be-measured (e.g., animals, people, etc.), the light may be reflected from the object-to-be-measured after reaching the object-to-be-measured, and the reflected light may be detected by a light receiving part in the optical distance sensing module. Because the propagation loss of the light may be very small and the transmission of the light may not be easily disturbed, the optical distance sensing module may calculate the distance between the sensor (the optical distance sensing module) and the object-to-be-measured by calculating the time difference and/or phase difference between the outgoing light and the reflected light.

It should be understood that the light transmitted and the light received by the optical distance sensing module in the present disclosure does not only refer to the visible light in daily life, but may also include invisible light such as light pulses, infrared rays, ultrasonic waves, etc., which may be less easily disturbed and for which it may not be easy to disturb the external environment. Depending on the object-to-be-measured and the application scenario, the function of the optical distance sensing module may be distance detection, motion recognition, etc.

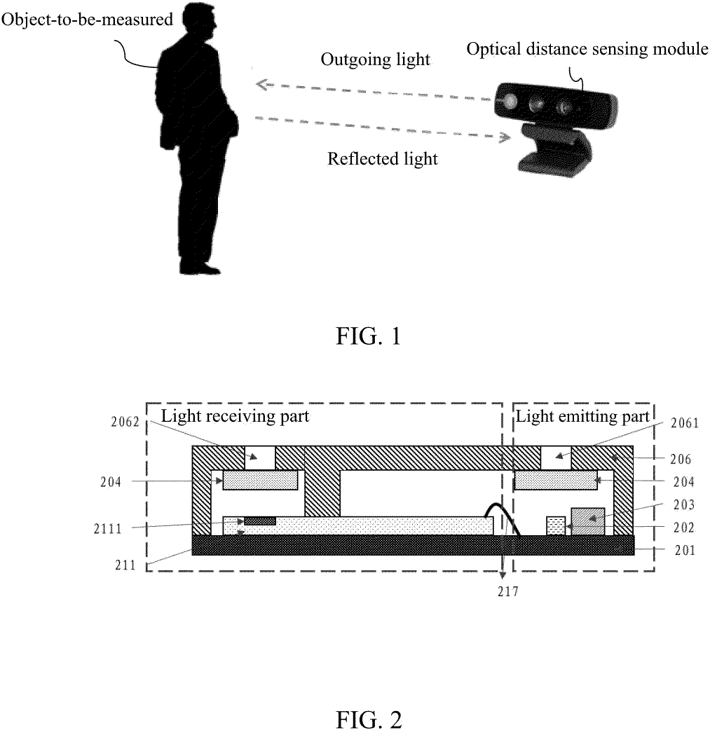

FIG. 2 is a schematic diagram showing the structure of an optical distance sensing module.

As shown in FIG. 2, the optical distance sensing module may include a substrate layer 201, a light emitting part and a light receiving part that are located on the substrate layer 201, and a housing 206. The light emitting part may include a light emitter 202 and a circuit element(s) 203 The light receiving part may include a light receiver (for example, including an optical sensing layer 211 with an array of optical sensing elements 2111), and the light emitting part and the light receiving part may be connected by wirings 217. The housing 206 may include a light exit hole(s) 2061 and a light incident hole(s) 2062 therein. A light filtering glass 204 may be installed under the housing 206. The light incident hole(s) 2062 may be arranged to face towards the light receiver. The light exit hole(s) 2061 may be arranged to face towards the light emitter 202, and the light emitted by the light emitter 202 may be transmitted to the object-to-be-measured through the light exit hole(s) 2061 after passing through the light filtering glass 204. The light reflected by the object-to-be-measured may pass through the light incident hole 2062, and may be filtered by the light filtering glass 204, and received by the light receiver. Thus, the optical distance sensing module can detect the distance between the external object and the optical distance sensing module through the time difference and/or phase difference between the light emitted by the optical transmitter 202 and the reflected light received by the light receiver.

The optical distance sensing module in FIG. 2 is generally fabricated in such a method that, the optical transmitter 202, the light receiver (including the optical sensing layer 211 with the array of optical sensing elements 2111), the substrate layer 201 and the circuit element(s) 203 on the substrate layer 201 are produced in advance. An appropriate housing packaging is designed according to the size of the light emitting part and the light receiving part, the housing 206 may be provided with the light incident hole(s) 2062 and the light exit hole(s) 2061, such that the light incident hole(s) 2062 is arranged to face towards the light receiver, and the light exit hole(s) 2061 is arranged to face towards the light transmitter 202.The light filtering glass 204 may be installed inside the housing and under the light incident hole(s) 2062 and the light exit hole(s) 2061. The respective components of the optical distance sensing module may be assembled together through pasting (e.g., with an adhesive) or through other structural connection manners. Because all parts of the optical distance sensing module fabricated by this method need to be assembled together after every part is produced, the assembly requires high precision and is difficult to realize. Moreover, due to the limitation of process technique, the size of the whole optical distance sensing module for processing is relatively large. As the optical distance sensing module in FIG. 2 adopts a housing to package the light emitting part and the light receiving part together, which has certain requirements on the strength and thickness of the housing, so the thickness of the whole optical distance sensing module is large and the weight is not ideal.

Typically, when the traditional fabricating method is adopted, the thickness of each layer of components usually exceeds 100 microns, while the thickness of the whole optical distance sensing module is about 1 to 1.5 mm. However, for some application scenarios, such as when the optical distance sensing module is applied to an intelligent terminal, it is necessary to further reduce the thickness of the optical distance sensing module due to the limited space under the screen of the intelligent terminal.

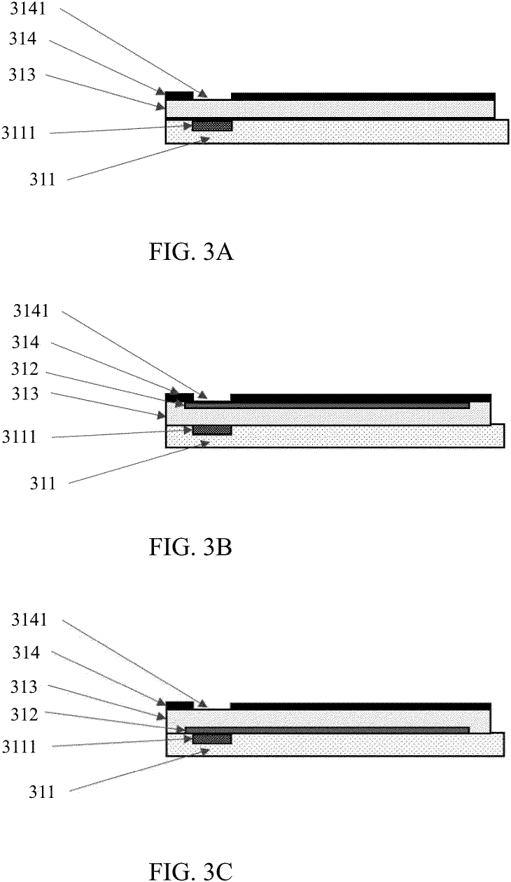

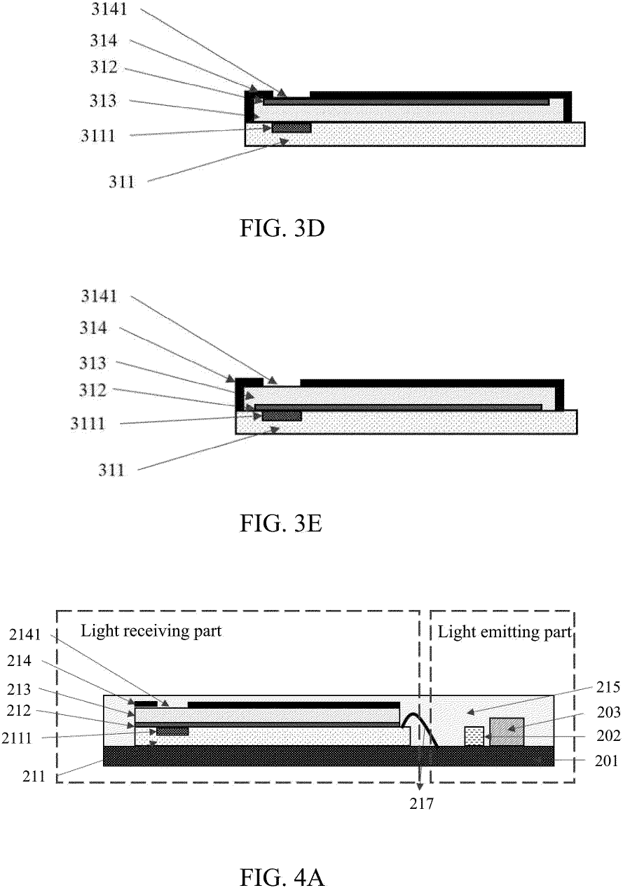

In order to reduce the size and weight of the optical distance sensing module and the light receiving part, the present disclosure proposes an optical sensor fabricated by wafer level packaging. FIGS. 3A to 3E are schematic diagrams showing the structure of an optical sensor according to one or more aspects of the present disclosure.

As shown in FIG. 3A, the optical sensor may include an optical sensing layer 311, a light transmitting layer 313, and a light blocking layer 314. The optical sensing layer 311 may include an array 3111 of optical sensing elements. The light transmitting layer 313 may be coated on the optical sensing layer 311 The light blocking layer 314 may include one or more light incident holes 3141 and may be coated on the light transmitting layer 313. The optical sensing layer 311, the light transmitting layer 313 and the light blocking layer 314 may be packaged as a wafer die. The light may pass through the light incident hole(s) 3141 and may transmit through the light transmitting layer 313 to irradiate on the array 3111 of optical sensing elements.

The traditional packaging step is mainly carried out after die dicing, that is, firstly dicing the wafer, and then packaging into various types of forms. In wafer level package (WLP), most of the processing processes are to operate on the wafer, that is, packaging as a whole is carried out on the wafer, and then dicing is carried out after packaging is completed. Because dicing is performed after packaging is completed, the size of the packaged chip is almost the same as that of the die, so it is also called CSP (Chip Scale Package) or WLCSP (Wafer Level Chip Scale Packaging). This type of packaging conforms to the market trend of light, small, short and thin consumer electronics, with benefits such as small parasitic capacitance and inductance, low cost and good heat dissipation. Moreover, since packaging as a whole is carried out on the wafer, and then dicing is carried out after the packaging is completed, packaging of hundreds or thousands of dies (chips) can be completed on a wafer at one time, which greatly saves the fabricating process and the fabricating time.

At present, a common optical sensing element may be a charge-coupled device (CCD), a metal oxide semiconductor device (CMOS) or a single photon avalanche diode (SPAD), etc. After the photosensitive pixel of CCD receives light, the CCD optical sensing element may generate corresponding current, the magnitude of which may correspond to the light intensity, and the CCD optical sensing element may directly output an electrical signal in analog form. Each CMOS optical sensing element may be directly integrated with an amplifier and an analog-to-digital conversion logic. If a photosensitive diode of the CMOS optical sensing element receives light and generates an analog electrical signal, the electrical signal may be first amplified by the amplifier of the CMOS optical sensing element and then directly converted into a corresponding digital signal. After receiving a single photon, each SPAD optical sensing element may amplify electron liberation by the avalanche multiplication technique and output a corresponding digital signal, so that a weak light band may also be detected. It should be understood that the main purpose of the CCD optical sensing element, the CMOS optical sensing element or the SPAD optical sensing element is to convert the collected optical signal into an electrical signal that can be processed by subsequent circuits or computers. All elements that can convert an optical signal into an electrical signal may belong to the optical sensing element described in the present disclosure.

Optionally, the optical sensor may further include a light filtering layer for filtering light in a specific wavelength range. Only light with a wavelength other than the specific wavelength range may be allowed to pass through the light filtering layer.

Optionally, in the case where the optical sensor includes a light filtering layer, the structure of the optical sensor may be as shown in FIG. 3B, that is, the light transmitting layer 313 may be coated on the optical sensing layer 311, and the light filtering layer 312 may be coated on the light transmitting layer 313. The optical sensing layer 311, the light filtering layer 312, the light transmitting layer 313 and the light blocking layer 314 may be packaged as a wafer die.

Optionally, in the case where the optical sensor includes the light filtering layer 312, the structure of the optical sensor may also be as shown in FIG. 3C, that is, the light filtering layer 312 may be coated on the optical sensing layer 311, and the light transmitting layer 313 may be coated on the light filtering layer 312. The optical sensing layer 311, the light filtering layer 312, the light transmitting layer 313 and the light blocking layer 314 may be packaged as a wafer die.

Optionally, in the case where the light filtering layer 312 is coated on the light transmitting layer 313, the light blocking layer 314 may be coated on an upper surface of the light filtering layer 312 (for example, the structure shown in FIG. 3B), or the light blocking layer 314 may be coated on the upper surface of the light filtering layer 312 and at least one side face of the light filtering layer 312 and/or the light transmitting layer 313 (for example, the structure shown in FIG. 3D)The light incident hole(s) 3141 of the light blocking layer 314 may be located on the upper surface of the light filtering layer 312.

Optionally, in the case where the light transmitting layer 313 is coated on the light filtering layer 312, the light blocking layer 314 may be coated on an upper surface of the light transmitting layer 313 (for example, the structure shown in FIG. 3C), or the light blocking layer 314 may be coated on the upper surface of the light transmitting layer 313 and at least one side face of the light filtering layer 312 and/or the light transmitting layer 313 (for example, the structure shown in FIG. 3E)The light incident hole(s) 3141 of the light blocking layer 314 may be located on the upper surface of the light transmitting layer 313.

As shown in FIGS. 3A to 3E, there may be no cavity structure in the optical sensor (i.e., the optical sensor may be solid or substantially solid) which may be fabricated by wafer level packaging according to present disclosure. Accordingly, the optical sensor structure may be more compact, which is different from the traditional packaging method. In the traditional packaging method, for example, as shown in FIG. 2, there is a cavity structure between the light filtering glass 204 under the light incident hole(s) 2062 and the light receiver. It should be understood that the light incident hole(s) according to the embodiments of the present disclosure do(es) not belong to the cavity structure.

Optionally, the optical sensor may further include a substrate layer that includes at least one circuit element, and the optical sensing layer 311 may be located on the substrate layer. The substrate layer may be a printed circuit board (PCB) or a flexible printed circuit board (FPC) including at least one circuit element and circuit wirings. The optical sensing layer 311 may be connected to the at least one circuit element by a wiring bonding connection, or may be connected to the at least one circuit element by a through silicon via (TSV) connection. It should be understood that the connection between the substrate layer and the optical sensing layer 311 may not be performed according to wafer level processing.

Optionally, the optical sensing layer 311, the light transmitting layer 313, and the light blocking layer 314 may form a light receiving part, or the optical sensing layer 311, the light transmitting layer 313, the light filtering layer 312, and the light blocking layer 314 may form the light receiving part, and the optical sensor may further include a molding layer which may package the light receiving part onto the substrate layer, and may shape and protects the optical sensor, and the light receiving part may be completely or partially covered by the molding layer. The molding layer may cover at least part of one or more light incident holes 3141, or may not not cover the one or more light incident holes 3141 at all. The characteristics of the molding layer will be described in detail below.

Optionally, the optical sensor may further include a light emitter which may be arranged on the substrate layer at a distance from the optical sensing layer 311. The light emitter may emit light, the light may be emitted to the outside through the optical sensor, and if the light is reflected by an external object, the reflected light may enter the light incident hole(s) 3141. The optical sensor may detect the distance between the external object and the optical sensor according to the time difference and/or phase difference between the light emitted by the light emitter and the reflected light received by the optical sensing element. It should be understood that the connection between the light emitter and the substrate layer may not be performed according to wafer level processing.

As respective components may be fabricated at the wafer level, assembly after production may be foregone. Instead, the optical sensing layer 311, the light transmitting layer 313 and the light blocking layer 314 may be combined together by adopting the semiconductor process (such as the manner of coating), and the light incident hole(s) 3141 may be fabricated on the light blocking layer 314 by patterning methods, for example, exposure, development, etching or peeling. Therefore, the size of the optical sensor can be effectively reduced, and the assembly precision of each layer may be significantly increased.

Through fabrication at the wafer level, the thickness of each of the light filtering layer 312, the light transmitting layer 313 and the light blocking layer 314 of the optical sensor may be less than 100 microns, and may be several microns or tens of microns, which can effectively reduce the thickness of the optical sensor compared with the traditional packaging method. Therefore, according to the embodiments of the present disclosure, the overall thickness of the optical sensor fabricated by wafer level packaging as described herein can be less than 1 mm, and even can be 0.5 mm, which may be more suitable for intelligent terminals.

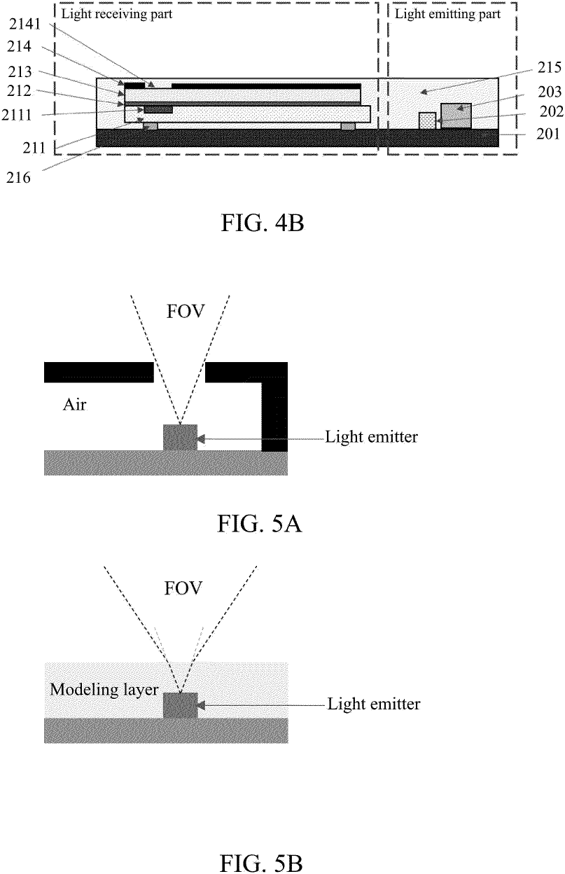

Similarly, in order to reduce the size and weight of the optical distance sensing module, aspects of the present disclosure relate to an optical distance sensing module using a light receiving part fabricated by wafer level packaging. FIGS. 4A and 4B are schematic diagrams showing the structure of an optical distance sensing module according to one or more aspects of the present disclosure.

As shown in FIGS. 4A and 4B, the optical distance sensing module may include a substrate layer 201, a light emitting part and a light receiving part that are located on the substrate layer 201, and a molding layer 215. The light emitting part may include a light emitter 202. The light receiving part may include an optical sensing layer 211, a light transmitting layer 213 and a light blocking layer 214. The optical sensing layer 211 may include an array of optical sensing elements 2111, the light transmitting layer 213 may be coated on the optical sensing layer 211, and the light blocking layer 214 may include one or more light incident holes 2141 and may be coated on the surface of the light transmitting layer 213. The optical sensing layer 211, the light transmitting layer 213 and the light blocking layer 214 may be packaged as a wafer die. The light emitting part and the light receiving part may be accommodated in the space defined by the molding layer 215 and the substrate layer 201, and may be arranged side by side on the substrate layer 201. The light emitter 202 may emit light, the light may be emitted to the outside through the molding layer 215 and may be reflected by an external object The reflected light may enter the light incident hole(s) 2141. Accordingly, the distance from the external object to the optical distance sensing module may be detected by the time difference and/or phase difference between the light emitted by the light emitter 202 and the reflected light received by the optical sensing element.

The light receiving part of the optical distance sensing module may adopt the design as shown in FIGS. 3A to 3E. That is, the light receiving part may further include a light filtering layer 212 for filtering light with a specific wavelength range. The light filtering layer 212 may be coated on the optical sensing layer 211, and the light transmitting layer 213 may be coated on the light filtering layer 212, or the light transmitting layer 213 may be coated on the optical sensing layer 211 and the light filtering layer 212 may be coated on the light transmitting layer 213. The optical sensing layer 211, the light filtering layer 212, the light transmitting layer 213 and the light blocking layer 214 may be packaged as a wafer die.

Optionally, in the case where the light transmitting layer 213 is coated on the light filtering layer 212, the light blocking layer 214 may be coated on an upper surface of the light transmitting layer 213, or the light blocking layer 214 may be coated on the upper surface of the light transmitting layer 213 and at least one side face of the light filtering layer 212 and/or the light transmitting layer 213, and the light incident hole(s) 2141 of the light blocking layer 214 may be located on the upper surface of the light transmitting layer 213. Where the light filtering layer 212 is coated on the light transmitting layer 213, the light blocking layer 214 may be coated on an upper surface of the light filtering layer 212, or the light blocking layer 214 may be coated on the upper surface of the light filtering layer 212 and at least one side face of the light filtering layer 212 and/or the light transmitting layer 213, and the light incident hole(s) 2141 of the light blocking layer 214 may be located on the upper surface of the light filtering layer 212.

Optionally, an optical isolating belt (not shown) may be provided between the light receiving part and the light emitting part of the optical distance sensing module as shown in FIGS. 4A and 4B. The optical isolating belt may function to reduce the chance of interference between the light emitted by the light emitting part of the optical distance sensing module and the light received by the light receiving part of the optical distance sensing module, so as to avoid affecting the ranging result of the optical distance sensing module.

Through fabrication at the wafer level, the thickness of each layer in the light receiving part of the optical distance sensing module may be less than 100 microns, may be several microns or tens of microns. Therefore, according to the embodiments of the present disclosure, the overall thickness of the light receiving part fabricated by wafer level packaging can be less than 1 mm, and even can be 0.5 mm, which may be more suitable for intelligent terminals.

Optionally, the substrate layer 201 of the optical distance sensing module may further include at least one circuit element 203, and the optical sensing layer 211 may be located on the substrate layer 201. The substrate layer 201 may be a PCB circuit board or an FPC circuit board including the at least one circuit element 203 and circuit wirings. The optical sensing layer 211 may be connected to the at least one circuit element by a wiring bonding connection (for example, in the illustrative structure shown in FIG. 4A, the optical sensing layer 211 is connected to the circuit element(s) 203 by the wiring 217), or it may be connected to the at least one circuit element by a through silicon via connection (for example, in the illustrative structure shown in FIG. 4B, the optical sensing layer 211 is connected to the circuit element(s) 203 by a through silicon via 216). It should be understood that the arrangement of the substrate layer 201 may be a conventional packaging.

As respective components may be fabricated at the wafer level, assembly after production may be avoided. The optical sensing layer 211, the light transmitting layer 213, and the light blocking layer 214 may be combined together by coating method, so the size of the optical distance sensing module can be effectively reduced, and the assembly precision of each layer may be increased. At the same time, because the packaging of the components avoids the sealed housing, but adopts the way of being filled with the molding layer, the weight of the optical distance sensing module may be reduced, and the thickness of the whole optical distance sensing module can be reduced.

The molding layer may be made of epoxy molding compound (EMC). The main raw material of EMC may be the resin-based material, and the rest of the components of EMC may be filer and hardener. After the powdered epoxy resin is melted, its viscosity may decrease when it dissolves into a gel state. If the temperature decreases, the epoxy resin may solidify, and the viscosity may increases inversely with the temperature. If the temperature is further lowered, the epoxy resin may be firmly bonded with the PCB circuit board, the lead frame, the wirings, the chip, etc. that are in the surrounding, and becomes a material with a relatively high hardness. In addition, after the material solidifies, when the semiconductor is put into use, if the temperature fluctuates, EMC can expand and contract along with the chip. In addition, this type of material may also facilitate heat dissipation. It should be understood that the manufacturing of the molding layer may be the conventional packaging.

In addition, according to the present disclosure, the overall thickness of the optical distance sensing module can be made smaller than 1 mm by packaging the optical distance sensing module using the molding layer, which may be more suitable for intelligent terminals. According to aspects of the present disclosure, in the application scenario of the optical distance sensing module, when the light emitting part and the light receiving part are packaged onto the substrate layer by molding, the molding layer may be made of transparent material, which may be used for packaging the light emitting part and the light receiving part on the substrate layer, shaping the optical distance sensing module, and protecting it from the external environment. Meanwhile, refractive index of the transparent molding material may be larger than that of air. In this case, due to the refraction of light, the light emitting range of the light emitter can be increased when an angle of the emitted light is certain.

FIGS. 5A and 5B are schematic diagrams showing the effect of the molding layer on the field of view (FOV) according to one or more aspects of the present disclosure.

FIG. 5A illustrates a case where there is air between the light emitter and the light exit hole in examples with a cavity structure similar to that shown in FIG. 2. The light emitter may include air as a propagation medium, and may emit light directly to the outside through the light exit hole. Because the light travels along a straight line, the field of view angle of light emission may be directly determined by the angle of the light emitted by the light emitter and the size of the light exit hole.

In FIG. 5B, the light emitting part does not have a light exit hole structure, and the outside of the light emitter is filled with the molding layer formed of the transparent material with a refractive index higher than that of air. If the light emitted by the light emitter has a certain angle, the light emitted by the light emitter may first take the molding layer as the propagation medium, and then may transmit to a contact surface between the molding layer and the air layer. After being refracted, the light may propagate in the air. Due to the refraction of the light, the light at this time may propagate according to the angle shown in the figure, and the field of view angle of light emission may be larger than that shown in FIG. 5A.

It can be seen from the comparison between FIG. 5A and FIG. 5B that the molding layer formed of the transparent material with the refractive index higher than that of air may increase the light emitting range of the light emitter when the angle of the light emitted by the light emitter is certain.

Similarly, by filling the molding layer formed of the transparent material with the refractive index higher than that of air outside the light incident hole(s) of the light receiver, the light receiving range of the light receiver may also be increased when the size of the light incident holes is certain.

The optical distance sensing module may have one light incident hole through which light is received by the optical sensing layer. The light intensity may be strong near the center of the incident hole, but lower at the edge. According to aspects, the center of the incident hole may be be as close to the center of the optical sensing layer as possible. In that way, more and stronger light may be received.

For the embodiment like that shown in FIG. 2, since the optical distance sensing module fabricated by this method needs to install parts together after they are produced, the installation error may be large, and it is easy to occur that the center of the light incident hole deviates from the center of the optical sensing layer, resulting in low light receiving efficiency.

However, for the embodiment in which the optical sensing layer, the light filtering layer, the light transmitting layer and the light blocking layer are packaged as the wafer die (for example, similar to the embodiment shown in FIGS. 4A and 4B), because of its high installation precision, it is easy to realize that the center of the light incident hole is as close to the center of the optical sensing layer as possible, so the light receiving efficiency may be increased.

Further, in order to improve the light receiving efficiency, it is also possible to use multiple light incident holes to receive light instead of one light incident hole to receive light. The multiple light incident holes may be distributed in an array. For example, the optical distance sensing module may have 16 light incident holes, which may be distributed in a 4×4 array. Through each light incident hole, light can be received by the optical sensing area on the optical sensing layer corresponding to the light incident hole. The light intensity at the center of each optical sensing area corresponding to the incident hole may be stronger, while the light intensity at the edge of the optical sensing area may be weaker. Although the area where the incident holes are located and the area where the optical sensing layer is located may be the same in size, the total light intensity received by 16 incident holes may be larger than that received by one incident hole. Therefore, the light receiving efficiency can be effectively improved by arranging multiple incident holes in an array.

It should be understood that, the case where the optical distance sensing module receives light is taken as an example herein, but not a limitation. For any optical sensor that includes the light incident hole(s) and the optical sensing layer, by increasing the number of the light incident holes, the light receiving efficiency can be made higher than that under the same light incident hole size. Optionally, multiple light incident holes may be distributed in an array.

As the optical distance sensing module in the present disclosure adopts wafer level processing to form the light transmitting layer on the optical sensing layer, to form the light blocking layer on the light transmitting layer, and to form one or more light incident holes on the light blocking layer. Compared with the optical distance sensing module fabricated by traditional fabricating method that respective parts are pasted or are assembled together in other structural connection manners after the respective parts of the optical distance sensing module are produced, and finally all the assembled parts are sealed and packaged, the optical distance sensing module in present disclosure may have a smaller size and volume. The optical distance sensing module fabricated by the traditional fabricating method may have a a larger size, and may only be placed in the rear camera of mobile phones, tablet computers and other electronic devices, but may not be arranged under the screen of an electronic device. By using the size advantage of the optical distance sensing module in the present disclosure, the optical distance sensing module can be arranged under the screen of electronic devices. By arranging the optical distance sensing module under the screen of the electronic device, the optical distance sensing module is enabled to detect the distance of things in front of the screen, recognize people’s actions, assist the front camera in focusing, etc., which has a broad development prospect.

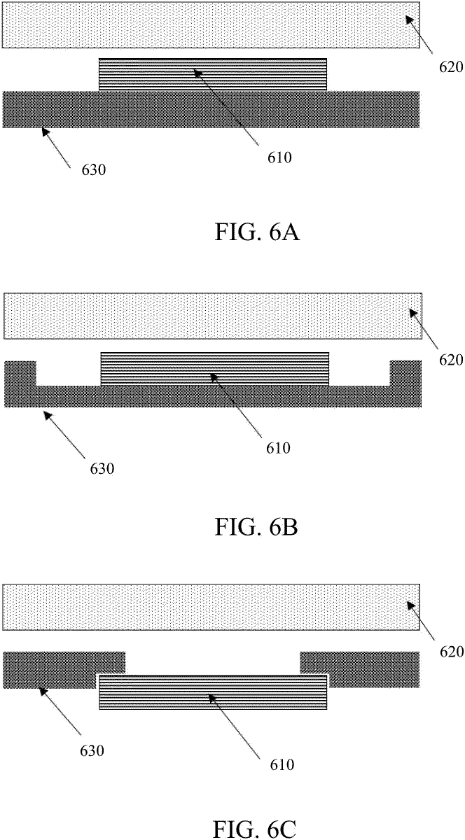

FIGS. 6A to 6C are schematic diagrams showing the installation manner of an optical distance sensing module according to the embodiments of the present disclosure. In the case where the optical distance sensing module 610 is arranged under the display screen 620 of the electronic device, the optical distance sensing module 610 may be connected with a middle frame 630 of the electronic device and is arranged under the display screen 620 of the electronic device through the middle frame 630 of the electronic device.

Optionally, as shown in FIGS. 6A and 6B, the optical distance sensing module 610 may be arranged between the display screen 620 and the middle frame 630 of an electronic device (e.g., mobile phone or a notebook computer). The middle frame 630 plays a supporting and fixing role, so that the optical distance sensing module 610 can be fixed under the display screen 620 of the electronic device. The optical distance sensing module 610 may transmit light and receive light through the display screen 620 to realize optical distance sensing.

Optionally, as shown in FIG. 6B, the middle frame 630 may have a groove on which the optical distance sensing module 610 is located. Accordingly, the optical distance sensing module 610 may be fixed between the display screen 620 and the middle frame 630 of the electronic device.

Optionally, as shown in FIG. 6C, the middle frame 630 may have an opening, and the optical distance sensing module 610 may be arranged to face towards the display screen 620 through the opening. Optionally, the lower surface of the opening of the middle frame 630 may be provided with a groove, and the optical distance sensing module 610 may be fixed to the lower surface of the groove. Optionally, the optical distance sensing module 610 may be partially or completely accommodated in the opening.

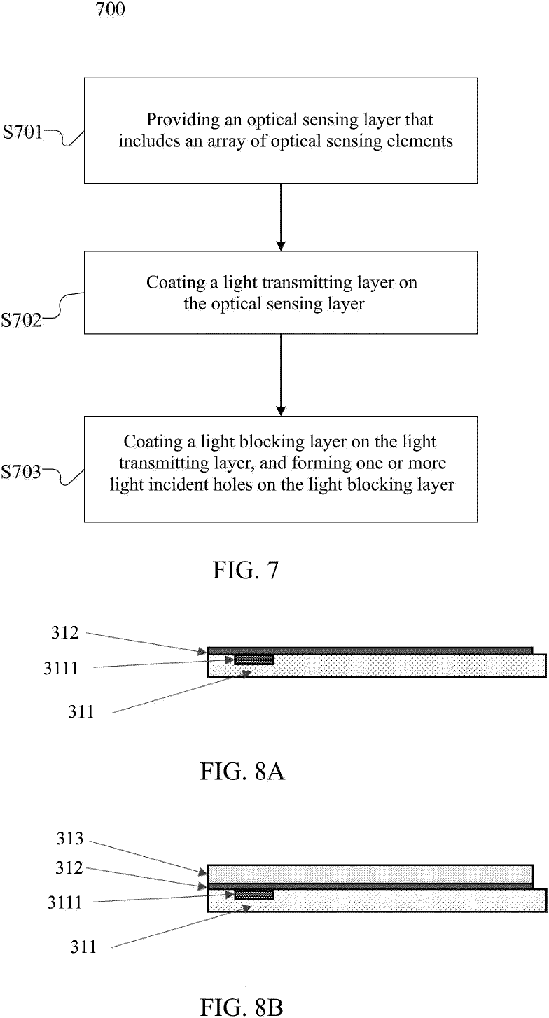

FIG. 7 is a schematic flowchart showing the fabricating method of an optical sensor according to one or more aspects of the present disclosure. The method 700 includes steps S701 to S703.

In step S701, an optical sensing layer including an array of optical sensing elements may be provided.

Optionally, the array of optical sensing elements may be a single photon avalanche diode (SPAD) array, a charge-coupled element (CCD) array and/or a metal oxide semiconductor (CMOS) array.

In step S702, a light transmitting layer may be coated on the optical sensing layer. For example, the light transmitting layer may be formed on the optical sensing layer by wafer level processing.

In step S703, a light blocking layer may be coated on the light transmitting layer, and one or more light incident holes may be formed on the light blocking layer. For example, the light blocking layer may be formed on the light transmitting layer by wafer level processing.

For steps S702 and S703, optionally, by wafer level processing, the light filtering layer may be coated on the optical sensing layer and the light transmitting layer may be coated on the light filtering layer, and then, by wafer level processing, the light blocking layer may be coated on an upper surface of the light transmitting layer or on the upper surface of the light transmitting layer and at least one side face of the light filtering layer and/or the light transmitting layer, and the light incident hole(s) of the light blocking layer may be located on the upper surface of the light transmitting layer.

For steps S702 and S703, optionally, by wafer level processing, the light filtering layer may be coated on the light transmitting layer and the light blocking layer may be coated on the light filtering layer. Then, by wafer level processing, the light blocking layer may be coated on an upper surface of the light filtering layer or on the upper surface of the light filtering layer and at least one side face of the light filtering layer and/or the light transmitting layer, and the light incident hole(s) of the light blocking layer may be located on the upper surface of the light filtering layer.

For step S703, optionally, the light blocking layer may include multiple light incident holes, and the multiple light incident holes may be distributed in an array.

The one or more light incident holes may be fabricated by wafer level processing, in which part of the light blocking layer in the light blocking layer may be removed by patterning such as exposure, development, etching or peeling to fabricate the light incident hole(s).

In addition, optionally, the optical sensing layer may be placed on the substrate layer. The substrate layer may include at least one circuit element, and the optical sensing layer may be connected with the at least one circuit element by a wiring bonding connection; or the optical sensing layer may be connected with the at least one circuit element by a through silicon via connection.

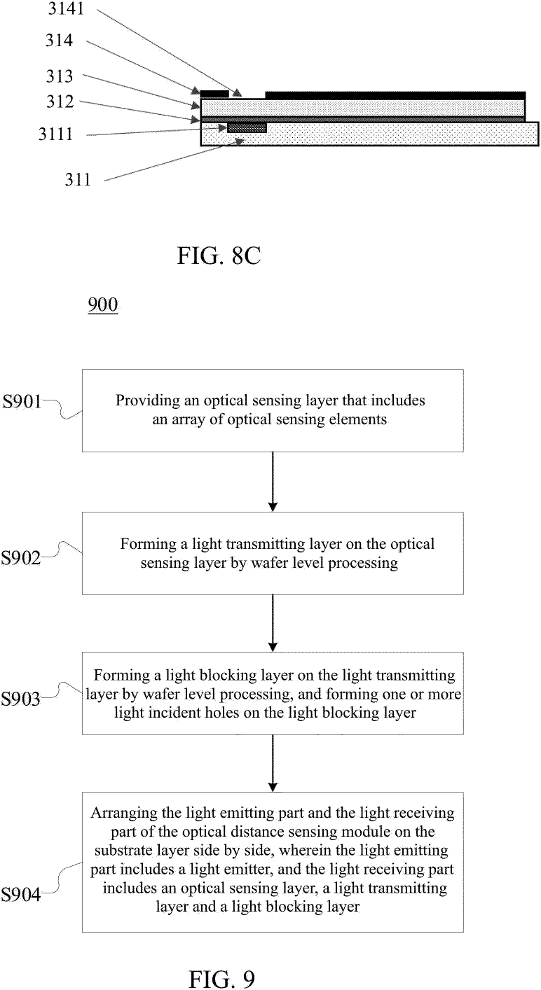

FIGS. 8A to 8C are schematic diagrams illustrating the fabricating method of an optical sensor according to the embodiments of the present disclosure.

In FIG. 8A, an optical sensing layer 311 is provided, and the optical sensing layer 311 may include an array of optical sensing elements 3111. A light filtering layer 312 may be coated on the optical sensing layer 311 by wafer level processing, and the light filtering layer 312 may be used for filtering light with a specific wavelength.

After the fabrication shown in FIG. 8A is completed, a light transmitting layer 313 may be coated on the light filtering layer 312 by wafer level processing, and then FIG. 8B is obtained.

After the fabrication shown in FIG. 8B is completed, the light blocking layer 314 may be coated on the upper surface of the light transmitting layer 313 by wafer level processing, and a light incident hole(s) 3141 may be formed by etching process, etc., so as to obtain FIG. 8C. The light incident hole(s) 3141 of the light blocking layer 314 may be located on the upper surface of the light transmitting layer 313.

In addition, it should be understood that although not shown in FIGS. 7 and 8A to 8C, the optical sensing layer 311, the light transmitting layer 313, and the light blocking layer 314 may be used to form the light receiving part of the optical sensor.Alternatively, the optical sensing layer 311, the light transmitting layer 313, the light filtering layer 312, and the light blocking layer 314 may be used to form the light receiving part of the optical sensor, and the light receiving part of the optical sensor may also be packaged onto the substrate layer by molding.

According to the embodiments of the present disclosure, the molding layer may be made of transparent material, which may be used to package the light receiving part on the substrate layer and shape the optical sensor. The molding layer may cover at least part of the one or more light incident holes 3141 or does not cover the one or more light incident holes 3141 at all.

It should be understood that FIGS. 8A to 8C only show an example of fabricating the optical sensor, and the optical sensor may not include the light filtering layer 312, or the light filtering layer 312 may be coated between the light transmitting layer 313 and the light blocking layer 314. Optionally, the light blocking layer 314 may be coated on the upper surface of the light transmitting layer 313 and at least one side face of the light filtering layer 312 and/or the light transmitting layer 313. Any type of the optical sensors shown in FIGS. 3A to 3E or a combination thereof may be fabricated by the methods shown in FIGS. 7 and 8A to 8C.

FIG. 9 is a schematic flowchart showing the fabricating method of an optical distance sensing module according to one or more aspects of the present disclosure. The method 900 includes steps S901 to S904.

In step S901, an optical sensing layer including an array of optical sensing elements may be provided.

Optionally, the array of optical sensing elements may be a charge-coupled element (CCD) array and/or a metal oxide semiconductor element (CMOS) array.

In step S902, a light transmitting layer may be formed on the optical sensing layer by wafer level processing.

In step S903, by wafer level processing, a light blocking layer may be formed on the light transmitting layer, and one or more light incident holes may be formed on the light blocking layer.

For steps S902 and S903, optionally, by wafer level processing, a light filtering layer may be coated on the optical sensing layer and a light transmitting layer may be coated on the light filtering layer, and then, by wafer level processing, a light blocking layer may be coated on an upper surface of the light transmitting layer or on the upper surface of the light transmitting layer and at least one side face of the light filtering layer and/or the light transmitting layer, and the light incident hole(s) of the light blocking layer may be located on the upper surface of the light transmitting layer.

For steps S902 and S903, optionally, by wafer level processing, a light filtering layer may be coated on the light transmitting layer and a light blocking layer may be coated on the light filtering layer. Then, by wafer level processing, a light blocking layer may be coated on an upper surface of the light filtering layer or on the upper surface of the light filtering layer and at least one side face of the light filtering layer and/or the light transmitting layer, and the light incident hole(s) of the light blocking layer may be located on the upper surface of the light filtering layer.

Optionally, multiple light incident holes may be distributed in an array.

In step S904, the light emitting part and the light receiving part of the optical distance sensing module may be arranged on the substrate layer side by side. The light emitting part may include a light emitter, and the light receiving part may include an optical sensing layer, a light transmitting layer and a light blocking layer. It should be understood that this step S904 may be a traditional packaging process.

Optionally, an optical isolating belt may be provided between the light receiving part and the light emitting part.

Optionally, the optical sensing layer may be connected with the at least one circuit element for the light receiving part on the substrate layer by a wiring bonding connection; or the optical sensing layer may be connected with the at least one circuit element used for the light receiving part on the substrate layer by a through silicon via connection.

Optionally, the method 900 may further include a step that the light emitting part and the light receiving part may be packaged onto the substrate layer by molding. It should be understood that this molding method may be a traditional molding packaging process.

The technique of packaging the chip by molding may mean that EMC is melted and then solidified to seal. Compared with the method of sealing the chip by attaching a ceramic plate or a metal cover plate, the method of packaging the chip by molding may have increased flexibility, lower price and lighter weight.

The molding packaging method generally includes transfer molding and compression molding.

The epoxy resin may be melted into a gel state by transfer molding, and then a certain pressure may be forced to flow it through a narrow path. As the chip becomes smaller and smaller, the number of layers may become more and more, and the lead structure may become more and more complex. Accordingly it may be difficult for epoxy resin to spread evenly in the molding process, resulting in incomplete molding or gaps. In order to solve this problem, some skilled in the art also use the method of applying pressure to injecting epoxy resin, while vacuuming to make the epoxy resin more evenly distributed, thus reducing gaps.

Compression molding may put EMC into a molding frame, then melts it, and thereafter vertically places the wafer on the gel epoxy resin to form the molding packaging. This method can reduce the problem of molding gaps, and at the same time, the amount of epoxy resin used in this method may be reduced, which saves the cost.

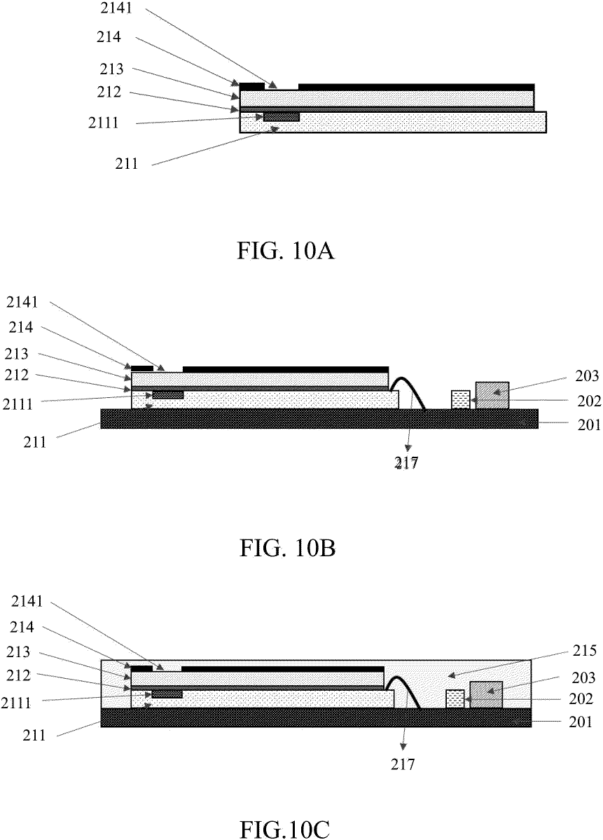

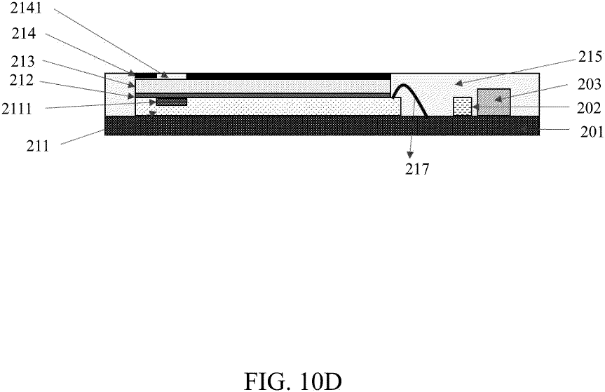

FIGS. 10A to 10D are schematic diagrams illustrating the fabricating method of an optical distance sensing module according to one or more aspects of the present disclosure.

It should be understood that the structure shown in FIG. 8C is only a single small structure on one piece of wafer, and in the wafer level packaging process of FIG. 8C, hundreds or thousands of small structures as shown in FIG. 8C may be included on the formed one piece of wafer. According to the actual use requirements, the wafer structure in FIG. 8C may needs to be diced again, so that FIG. 10A can be obtained. The structure in FIG. 8C may have the same thickness as the structure in FIG. 10A, but the structure in FIG. 10A may only be a single small structure.

FIG. 10B can be obtained by taking the structure in FIG. 10A as the light receiving part of the optical distance sensing module, locating the optical sensing layer on the substrate layer 201, and arranging the light emitting part and the light receiving part of the optical distance sensing module on the substrate layer 201 side by side. The light emitting part may include the light emitter 202 and the circuit element(s) 203. The light receiving part may include the optical sensing layer, the light transmitting layer and the light blocking layer.

The substrate layer 201 may include, thereon, at least one circuit element 203. The optical sensing layer may be connected with the circuit element(s) 203 by a wiring bonding connection; or the optical sensing layer may be connected with the circuit element(s) 203 by a through silicon via connection, so that the optical sensing layer can communicate signals with the circuit element(s) 203 on the substrate layer 201.

With respect to the structure in FIG. 10B, the light emitting part and the light receiving part may be completely or partially packaged onto the substrate layer 201 by molding. The molding layer 215 may be made of transparent material, which may be used to package the light emitting part and the light receiving part onto the substrate layer 201 and shape the optical distance sensing module. Furthermore, the refractive index of the transparent material may be larger than that of air to increase the range of light emission or reception.

For instance, in the example shown in FIG. 10C, the light emitting part and the light receiving part are completely covered by the molding layer. Optionally, the light emitting part and the light receiving part may be partially covered by the molding layer 215. For example, in the example shown in FIG. 10D, the molding layer 215 covers the light emitting part completely and covers only the periphery of the light receiving part, but does not cover the upper surface of the light receiving part. Optionally, the light incident hole(s) may be or may not be filled with the molding layer. In addition, the molding layer may only cover part of the light emitter, etc.

The thickness of each layer in the light receiving part of the optical distance sensing module fabricated by wafer level packaging may be less than 100 microns, and may be several microns or tens of microns. Therefore, according to the embodiments of the present disclosure, the overall thickness of the light receiving part fabricated by wafer level packaging may be less than 1 mm, and even can be 0.5 mm, and the overall thickness of the optical distance sensing module may be less than 1 mm, which may be more suitable for intelligent terminals.

Therefore, the present disclosure provides an optical sensor, an optical distance sensing module and their fabricating methods.

According to the embodiments of the present disclosure, the optical sensor may comprise an optical sensing layer, a light transmitting layer and a light blocking layer, wherein the optical sensing layer may include an array of optical sensing elements; the light transmitting layer may be coated on the optical sensing layer; the light blocking layer may include one or more light incident holes and may be coated on the light transmitting layer. The optical sensing layer, the light transmitting layer and the light blocking layer may be packaged as a wafer die; light may pass through the light incident holes and irradiate the array of optical sensing elements through the light transmitting layer. The optical sensor provided by the present disclosure can effectively reduce the thickness, size and weight of the optical sensor, thereby expanding the application range of the optical sensor.

The present disclosure uses specific words to describe the examples and aspects of the present disclosure. Some features, structures, or features in one or more embodiments of the present disclosure may be appropriately combined.

Unless otherwise defined, all terms (including technical and scientific terms) used herein have the same meaning as commonly understood by those of ordinary skill in the art to which the aspects belong. It will be further understood that terms, such as those defined in commonly used dictionaries, should be interpreted as having the meaning that is consistent with their meaning in the context of the relevant art and will not be interpreted in an idealized or overly formal sense unless expressly defined as such herein.

The above is illustration of the present disclosure and should not be considered as a limitation thereof. Although some illustrative aspects of the present disclosure have been described, those skilled in the art can easily understand that many modifications may be made to these illustrative aspects without departing from the teachings and advantages of the present disclosure. Therefore, all such modifications are intended to be included within the scope of the present disclosure as defined by the appended claims. As will be appreciated, the above is to explain the present disclosure, it should not be constructed as being limited to the specific aspects and examples disclosed, and modifications to the aspects and examples of the present disclosure and other embodiments are intended to be included within the scope of the attached claims. The present disclosure is defined by the claims and their equivalents.

What is claimed is:

1. An optical sensor, comprising:
an optical sensing layer comprising an array of optical sensing elements;
a light transmitting layer coated on the optical sensing layer; and
a light blocking layer coated on the light transmitting layer, the light blocking layer comprising one or more light incident holes,
wherein the optical sensing layer, the light transmitting layer and the light blocking layer are packaged as a wafer die,
wherein light passes through the one or more light incident holes and transmits through the light transmitting layer to irradiate on the array of optical sensing elements.

2. The optical sensor according to claim 1, further comprising:
a light filtering layer for filtering light in a specific wavelength range, wherein the light filtering layer, the optical sensing layer, and the light transmitting layer are arranged at least one of where:
the light filtering layer is coated on the optical sensing layer, and the light transmitting layer is coated on the light filtering layer; or
the light transmitting layer is coated on the optical sensing layer, and the light filtering layer is coated on the light transmitting layer,
wherein the optical sensing layer, the light filtering layer, the light transmitting layer and the light blocking layer are packaged as the wafer die.

3. The optical sensor according to claim 2, wherein where the light transmitting layer is coated on the light filtering layer, the light blocking layer is coated on at least one of:
an upper surface of the light transmitting layer; or
the light blocking layer is coated on the upper surface of the light transmitting layer and at least one of:
at least one side face of the light filtering layer; or
at least one side face of the light transmitting layer, and
wherein the one or more light incident holes of the light blocking layer are located on the upper surface of the light transmitting layer; and
where the light filtering layer is coated on the light transmitting layer, the light blocking layer is coated on at least one of:
an upper surface of the light filtering layer; or
the light blocking layer is coated on the upper surface of the light filtering layer and at least one of:
at least one side face of the light filtering layer; or
at least one side of the light transmitting layer, and
wherein the one or more light incident holes of the light blocking layer are located on the upper surface of the light filtering layer.

4. The optical sensor according to claim 1, wherein the light blocking layer comprises multiple light incident holes distributed in an array.

5. The optical sensor according to claim 1 wherein a thickness of each layer in the optical sensor is less than 100 microns.

6. The optical sensor according to claim 1, wherein the optical sensor is substantially solid.

7. The optical sensor of claim 1, further comprising: a substrate layer comprising at least one circuit element,
wherein the optical sensing layer is located on the substrate layer and connected to the at least one circuit element by at least one of:
a wiring bonding connection; or
a through silicon via (TSV) connection.

8. The optical sensor of claim 7, further comprising:
a light receiving part located on the substrate layer, and a molding layer,
wherein the light receiving part comprises the optical sensing layer, the light transmitting layer and the light blocking layer;
the molding layer packages the light receiving part onto the substrate layer and shapes the optical sensor, and the light receiving part is at least one of: completely, or partially covered by the molding layer.

9. The optical sensor of claim 8, wherein the molding layer is made of transparent material, and the molding layer covers at least one of:
part of the one or more light incident holes, or
the molding layer does not cover the one or more light incident holes at all.

10. The optical sensor according to claim 9, wherein a refractive index of the transparent material is higher than a refractive index of air, so that a light receiving range of the light receiving part is increased.

11. An optical sensor fabricating method, comprising:
providing an optical sensing layer comprising an array of optical sensing elements;
forming a light transmitting layer on the optical sensing layer by wafer level processing;
forming a light blocking layer on the light transmitting layer by wafer level processing; and
forming one or more light incident holes in the light blocking layer.

12. The optical sensor fabricating method according to claim 11, wherein forming the light transmitting layer on the optical sensing layer comprises:
coating a light filtering layer on the optical sensing layer and coating the light transmitting layer on the light filtering layer by wafer level processing,
wherein forming the light blocking layer on the light transmitting layer comprises at least one of:
coating the light blocking layer on an upper surface of the light transmitting layer; or
coating the light blocking layer on at least one of:
the upper surface of the light transmitting layer and at least one of:
at least one side face of the light filtering layer; or
at least one side face of the light transmitting layer by wafer level processing; and
locating the one or more light incident holes of the light blocking layer on the upper surface of the light transmitting layer.

13. The optical sensor fabricating method according to claim 11, wherein forming the light blocking layer on the light transmitting layer further comprises:
coating a light filtering layer on the light transmitting layer and coating the light blocking layer on the light filtering layer by wafer level processing,
wherein coating the light blocking layer on the light filtering layer comprises at least one of:
coating the light blocking layer on an upper surface of the filtering layer; or
coating the light blocking layer on an upper surface of the light filtering layer and at least one of:
at least one side face of the light filtering layer; or
at least one side face of the light transmitting layer by wafer level processing; and
locating the one or more light incident holes of the light blocking layer on the upper surface of the light filtering layer.

14. The optical sensor fabricating method according to claim 11, wherein, multiple light incident holes are formed on the light blocking layer, and the optical sensor fabricating method further comprises:
distributing the multiple light incident holes in an array.

15. The optical sensor fabricating method according to claim 11, wherein thickness of each layer in the optical sensor fabricated by the optical sensor fabricating method is less than 100 microns.

16. The optical sensor fabricating method according to claim 11, wherein the optical sensors is substantially solid.

17. The optical sensor fabricating method according to claim 11, further comprising:
locating the optical sensing layer on a substrate layer, wherein the substrate layer comprises at least one circuit element; and
connecting the optical sensing layer with the at least one circuit element by at least one of:
a wiring bonding connection; or
connecting the optical sensing layer with the at least one circuit element by a through silicon via (TSV) connection.

18. The optical sensor fabricating method according to claim 11, further comprising:
arranging a light receiving part of the optical sensor on a substrate layer, wherein the light receiving part comprises the optical sensing layer, the light transmitting layer and the light blocking layer, and
packaging the light receiving part of the optical sensor onto the substrate layer by molding.

19. An optical distance sensing module, comprising:
a substrate layer;
a light emitting part located on the substrate layer; and
a light receiving part located on the substrate layer,
wherein the light emitting part comprises a light emitter, and the light receiving part comprises an optical sensing layer, a light transmitting layer and a light blocking layer, wherein the optical sensing layer comprises an array of optical sensing elements; the light transmitting layer is coated on the optical sensing layer; the light blocking layer comprises one or more light incident holes and is coated on a surface of the light transmitting layer;
wherein, the optical sensing layer, the light transmitting layer and the light blocking layer are packaged as a wafer die;
the light emitting part and the light receiving part are arranged side by side on the substrate layer, the light emitter emits light, the light is reflected by an external object and then the reflected light enters the one or more light incident holes,
wherein the optical distance sensing module detects a distance between the external object and the optical distance sensing module through at least one of:
a time difference or phase difference between the light emitted by the light emitter and the reflected light received by the optical sensing element.

20. The optical distance sensing module according to claim 19, wherein the optical distance sensing module further comprises:
an optical isolation belt for performing optical isolation between the light receiving part and the light emitting part.

21. The optical distance sensing module according to claim 19, wherein the substrate layer comprises at least one circuit element for the light receiving part and at least one circuit element for the light emitting part,
wherein, the optical sensing layer is located on the substrate layer, and is connected to the at least one circuit element for the light receiving part by at least one of:
a wiring bonding connection; or
a through silicon via (TSV) connection.

22. The optical distance sensing module according to claim 19, wherein the optical distance sensing module is arranged under a display screen of an electronic device,
wherein, the electronic device comprises a middle frame, and the optical distance sensing module is connected to the middle frame.

23. The optical distance sensing module according to claim 22, wherein the optical distance sensing module is arranged between the display screen and the middle frame of the electronic device.

24. The optical distance sensing module according to claim 22, wherein
the middle frame has a groove, and the optical distance sensing module is located on the groove.

25. The optical distance sensing module according to claim 22, wherein,
the middle frame has an opening, and the optical distance sensing module is arranged to face towards the display screen through the opening.

26. The optical distance sensing module according to claim 22, wherein the optical distance sensing module is at least one of partially or completely accommodated in the opening.

27. The optical distance sensing module according to claim 22, wherein a lower surface of the opening of the middle frame is provided with a groove, and the optical distance sensing module is fixed to the lower surface of the groove.

28. The optical distance sensing module according to claim 19, further comprising:
a molding layer,
the light emitting part and the light receiving part are at least one of completely or partially covered by the molding layer, wherein the light emitter emits light transmitting through the molding layer.

29. The optical distance sensing module according to claim 28, wherein the molding layer is made of transparent material, which is used for packaging the light emitting part and the light receiving part on the substrate layer and shaping the optical distance sensing module.

30. The optical distance sensing module according to claim 29, wherein a refractive index of the transparent material is higher than that of air, so that a light receiving range of the light receiving part is increased.
